(19) United States
(12) Patent Application Publication
(10) Pub. No.: US 2002/0167334 A1
(43) Pub. Date: Nov. 14, 2002

(54) Semiconductor integrated circuit

(75) Inventor: Kazuo Nakaizumi, Kawasaki-shi (JP)

Correspondence Address: DARBY & DARBY P.C., 805 Third Avenue, New York, NY, 10022, US

(73) Assignee: Ando Electric Co., Ltd.

(21) Appl. No.: 10/141,165

(22) Filed: May 7, 2002

(30) Foreign Application Priority Data
May 9, 2001 (JP) P2001-139003

(51) Int. Cl. H03K 19/00

(52) U.S. Cl. 326/93

(57) ABSTRACT

A semiconductor integrated circuit is constituted by a logic circuit, auxiliary logic circuits, and a selection circuit For example, the logic circuit contains unit inverters, and the auxiliary logic circuits are each correspondingly constituted by a pair of unit inverters. The selection circuit selectively activates the auxiliary logic circuit(s) relatively with the logic circuit in response to the period of the input clock signal (CLK2S), supplied to the logic circuit, which is not smaller than the prescribed shortest period (T1). Even though the average current flowing in the logic circuit decreases due to the relatively long period of the input clock signal, it is possible to compensate for the power deficiency by adequately activating the auxiliary logic circuit(s). Therefore, substantially no variation occurs in the junction temperature and jitter with respect to transistors contained in the logic circuit, regardless of variations of the input clock signal.

### BACKGROUND OF THE INVENTION

1. Field of the Invention

This invention relates to semiconductor integrated circuits for use in semiconductor integrated circuit testing devices (e.g., IC testers) that require a high accuracy in measurement of integrated circuits and large-scale integrated circuits with respect to time.

2. Description of the Related Art

Recent technologies such as information technologies develop numerous electronic devices, which are composed of numerous semiconductor integrated circuits such as integrated circuits (ICs) and large-scale integrated circuits (LSI circuits). In order to reduce the amounts of electrical energy consumed, semiconductor integrated circuits are frequency composed of complementary metal-oxide semiconductor (CMOS) circuits. For example, the typical example of a CMOS inverter circuit contains a p-channel transistor and an n-channel transistor. FIG. 6 shows the configuration of a conventional CMOS inverter circuit, namely, a CMOS inverter circuit 20 that is constituted by connecting together unit inverters 20a, 20b, . . . in a cascade-connection manner. Normally, several tens of the unit inverters 20a, 20b, . . . are connected together in the cascade-connection manner to form a single CMOS inverter circuit 20.

The unit inverter 20a of the inverter circuit 20 is composed of a p-channel MOS transistor (hereinafter, referred to as a PMOS transistor) 21a and an n-channel MOS transistor (hereinafter, referred to as an NMOS transistor) 22a. Both the gate electrode of the PMOS transistor 21a and the gate electrode of the NMOS transistor 22a are connected to an input terminal 23a. Both the drain electrode of the PMOS transistor 21a and the source electrode of the NMOS transistor 22a are connected to an output terminal 24a. In addition, the source electrode of the PMOS transistor 21a is connected to a power source Vcc, and the drain electrode of the NMOS transistor 22a is grounded.

The unit inverter 20b is constituted similarly to the aforementioned unit inverter 20a. That is, the unit inverter 20b is composed of a PMOS transistor 21b and an NMOS transistor 22b. Both the gate electrode of the PMOS transistor 21b and the gate electrode of the NMOS transistor 22b are connected to an input terminal 23b. Both the drain electrode of the PMOS transistor 21b and the source electrode of the NMOS transistor 22b are connected to an output terminal 24b. In addition, the source electrode of the PMOS transistor 21b is connected to a power source Vcc, and the drain electrode of the NMOS transistor 22b is grounded. The unit inverters 20a and 20b are connected together in series in such a way that the output terminal 24a of the unit inverter 20a is connected to the input terminal 23b of the unit inverter 20b.

Next, the overall operation of the inverter circuit 20 will be described with reference to FIGS. 7A to 7D. A clock signal CLK1 shown in FIG. 7A is input to the input terminal 23a of the unit inverter 20a shown in FIG. 6. The clock signal CLK1 provides various periods corresponding to minimal cycles, wherein it can be varied in frequency by its cycles respectively. The minimal cycles for the clock signal CLK1 approximately range from 1 ns to 10 ns, for example.

FIG. 7B shows variations of a transient current I₁ that flows in the unit inverter 20a to enable switching of the PMOS transistor 21a and the NMOS transistor 22a respectively. Herein, the transient current I₁ may contain the charging current, discharging current, and through current. FIG. 7C shows junction temperature tⱼ. FIG. 7D shows a time difference t_{pd}, which represents an overall time difference measured between the input signal and output signal of an inverter circuit 20 shown in FIG. 8. In other words, the simplified block diagram of FIG. 8 is provided for explaining a response time t_{pd} that is set to the inverter circuit 20.

The clock signal CLK1 shown in FIG. 7A is intermittently changed over in frequency. That is, the clock signal CLK1 has a relatively high frequency during the time period between t₃₁ and t₃₄, wherein the minimal cycle period ranges from 2 ns to 10 ns, for example. That is, clock pulses of the clock signal CLK1 whose period ranges from 2 ns to 10 ns are sequentially input to the unit inverter 20a during the time period between t₃₁, and t₃₄. In this time period, both the PMOS transistor 21a and the NMOS transistor 22a repeatedly perform high-speed switching operations. Therefore, in this time period, it is assumed that an average current I_{AV} (see FIG. 7B) flows through the PMOS transistor 21a and the NMOS transistor 22a respectively.

At the initial stage where no clock pulse is input to the unit inverter 20a, the junction temperature tⱼ may be approximately set to 25° C. As clock pulses of the clock signal CLK1 are sequentially input to the unit inverter 20a, the junction temperature tⱼ is gradually increased from the initial temperature (i.e., 20° C.) to reach a certain high temperature that is about 75° C. In addition, the response time t_{pd}, which is initially set to 1600 ps, is correspondingly increased to 2000 ps. This circuitry shows that the junction temperature tⱼ is increased to 75° C. while the response time t_{pd} is correspondingly increased to 2000 ps as the PMOS transistor 21a and the NMOS transistor 22a perform high-speed switching operations. Of course, these values are only examples; hence, they may be easily changed by providing the prescribed heat radiation or dissipation means using the heatsink and the like.

In the time period T2 between t₃₄ and t₃₅, the clock signal CLK1 input to the unit inverter 20a is considerably reduced so that only one clock pulse is input to the unit inverter 20a within 10 ms, for example. In this time period T2 between t₃₄ and t₃₅, each of the PMOS transistor 21a and the NMOS transistor 22a performs a switching operation one time. That is, substantially no transient current flows through the PMOS transistor 21a and the NMOS transistor 22a, so that the junction temperature tⱼ is reduced to the initial temperature, which is about 25° C. and which was measured before inputting the clock signal CLK1 to the unit inverter 20a. In addition, the response time t_{pd} is reduced to the initial time 1600 ps, which was measured before inputting the clock signal CLK1 to the unit inverter 20a.

As described above, in the high-speed operation period (e.g., t₃₁-t₃₄) of the unit inverter 20a, the transient current flows through the PMOS transistor 21a and the NMOS transistor 22a, whereas in the high-speed operation period (e.g., t₃₄-t₃₅), substantially no transient current flows through the PMOS transistor 21a and the NMOS transistor 22a. The other unit inverters (e.g., 20b) may operate similarly to the aforementioned unit inverter 20a.

The aforementioned operation may cause differences in electricity consumed by each unit inverter (e.g., 20a) in response to the clock signal CLK1. In the aforementioned example, there occurs a temperature difference of about 50° C. between the junction temperatures t^{j}that are measured in a high-speed operation mode and a low-speed operation mode respectively. In addition, there occurs a time difference of about 400 ps between the response times t_{pd} that are measured in the high-speed operation mode and low-speed operation mode respectively.

The aforementioned time difference of 400 ps may cause jitters. In the case of the highly accurate measuring device such as the LSI tester, its standard may strictly regulate the jitter value not to be greater than 200 ps, for example. For this reason, the aforementioned inverter circuit providing a relatively large jitter value cannot be applied to the highly accurate measuring device. Although FIGS. 6, 7A-7D, and 8 are used to explain the inverter circuit as an example of the semiconductor integrated circuit, the aforementioned problem may generally occur in other semiconductor integrated circuits composed of CMOS circuits.

### SUMMARY OF THE INVENTION

It is an object of the invention to provide a semiconductor integrated circuit that is suitable for use in testing devices such as IC testers requiring a high accuracy in measurement with respect to time. The semiconductor integrated circuit of this invention causes substantially no variations in jitter and junction temperature, regardless of variations of the input clock frequency.

A semiconductor integrated circuit of this invention is basically constituted by a logic circuit, auxiliary logic circuits, and a selection circuit. For example, the logic circuit contains unit inverters each of which is composed of a pair of CMOS transistors, so that each of the auxiliary logic circuits is correspondingly constituted by a pair of unit inverters. The selection circuit is constituted by flip-flops that operate in accordance with a reference clock signal (CLK1) whose period is smaller than the period of an input clock signal (CLK2S) supplied to the logic circuit.

In the above, the selection circuit selectively activates the auxiliary logic circuit(s) relatively with the logic circuit in response to the period of the input clock signal supplied to the logic circuit. Even though the average current flowing in the logic circuit decreases due to the relatively long period of the input clock signal, the selection circuit selectively activates the auxiliary logic circuit(s) relatively with the logic circuit in response to the period of the input clock signal. That is, it is possible to compensate for the power deficiency by adequately activating the auxiliary logic circuit(s). Therefore, substantially no variation occurs in the junction temperature and jitter with respect to the transistors contained in the logic circuit. In addition, it is possible to perform high-precision controls on the variations of the junction temperature and jitter. Thus, the semiconductor integrated circuit of this invention is suitable for use in the highly accurate measuring device such as the IC tester.

It is preferable that the internal configuration of the auxiliary logic circuit may partially match the internal configuration of the logic circuit. In addition, this invention is characterized by the selection circuit sequentially activating the auxiliary logic circuits at different timings respectively. Further, this invention is also characterized by the selection circuit sequentially activating the auxiliary logic circuits unless the period of the input clock signal is not smaller than the prescribed shortest period (T1) that is determined in advance. Furthermore, the selection circuit operates in accordance with the reference clock signal (CLK1) whose period is smaller than the prescribed shortest period.

Incidentally, it is preferable that the auxiliary logic circuits be formed in proximity to the logic circuit. In addition, each of the transistors contained in the auxiliary logic circuits has a size that is 1/n (where ‘n’ is a natural number arbitrarily selected) times smaller than the size set for each of the transistors contained in the logic circuit.

Thus, the semiconductor integrated circuit of this invention causes substantially no variation in the junction temperature and jitter with respect to the transistors, regardless of variations of the input clock signal of the logic circuit.

### BRIEF DESCRIPTION OF THE DRAWINGS

These and other objects, aspects, and embodiments of the present invention will be described in more detail with reference to the following drawing figures, in which:

FIG. 1 is a circuit block diagram showing the configuration of a semiconductor integrated circuit in accordance with a preferred embodiment of the invention;

FIG. 2 is a circuit diagram showing an example of the internal configuration of an auxiliary logic circuit shown in FIG. 1;

FIG. 3 is a block diagram showing an example of the configuration of a clock generator circuit that generates clock signals CLK2S and CLK2C as well as a reset signal CLK2R;

FIG. 4A is a time chart showing a clock signal CLK1 input to the clock generator circuit;

FIG. 4B is a time chart showing a clock signal CLK2 input to the clock generator circuit;

FIG. 4C is a time chart showing a reset signal RST input to the clock generator circuit;

FIG. 4D is a time chart showing the clock signal CLK2S generated by the clock generator circuit;

FIG. 4E is a time chart showing the reset signal CLK2R generated by the clock generator circuit;

FIG. 4F is a time chart showing the clock signal CLK2C generated by the clock generator circuit;

FIG. 4G is a time chart showing a clock signal CLK3a input to an auxiliary logic circuit 13a shown in FIG. 1;

FIG. 4H is a time chart showing a clock signal CLK3b input to an auxiliary logic circuit 13b shown in FIG. 1;

FIG. 4I is a time chart showing a clock signal CLK3c input to an auxiliary logic circuit 13c shown in FIG. 1;

FIG. 4J is a time chart showing a clock signal-CLK3d input to an auxiliary logic circuit 13d shown in FIG. 1;

FIG. 4K is a time chart showing a clock signal CLK3e input to an auxiliary logic circuit 13e shown in FIG. 1;

FIG. 4L is a time chart showing a transient current I₁ that flows in a logic circuit shown in FIG. 1;

FIG. 4M is a time chart showing a current I₂ that flows through each of the auxiliary logic circuits shown in FIG. 1;

FIG. 4N is a time chart showing a total current I_{T} that is a sum of the currents I₁ and I₂;

FIG. 40 is a time chart showing a junction temperature tⱼ that is measured in the semiconductor integrated circuit of FIG. 1;

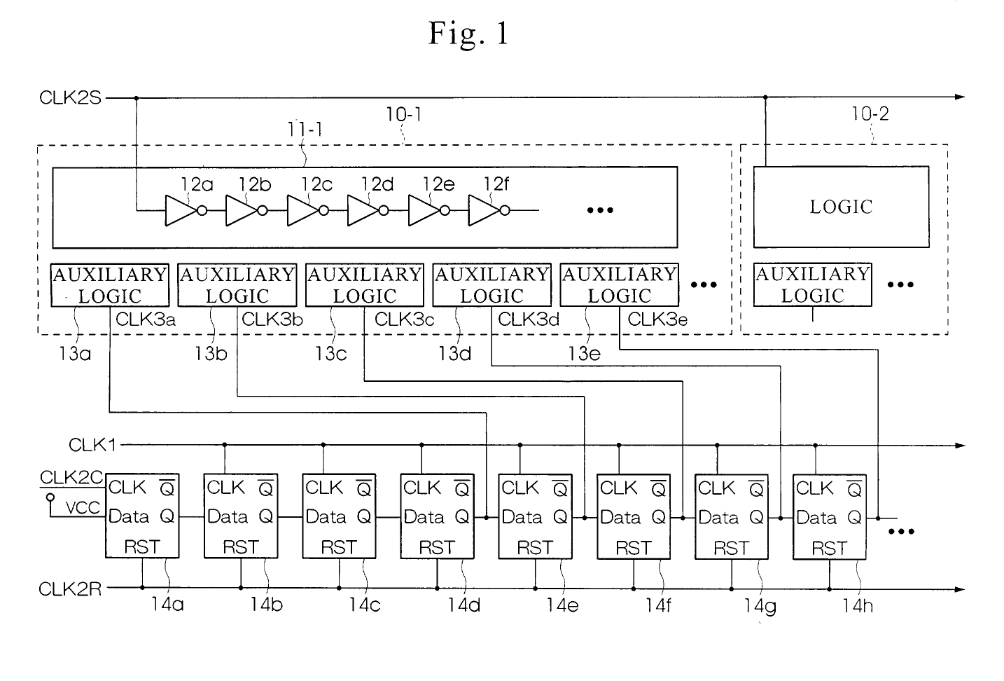

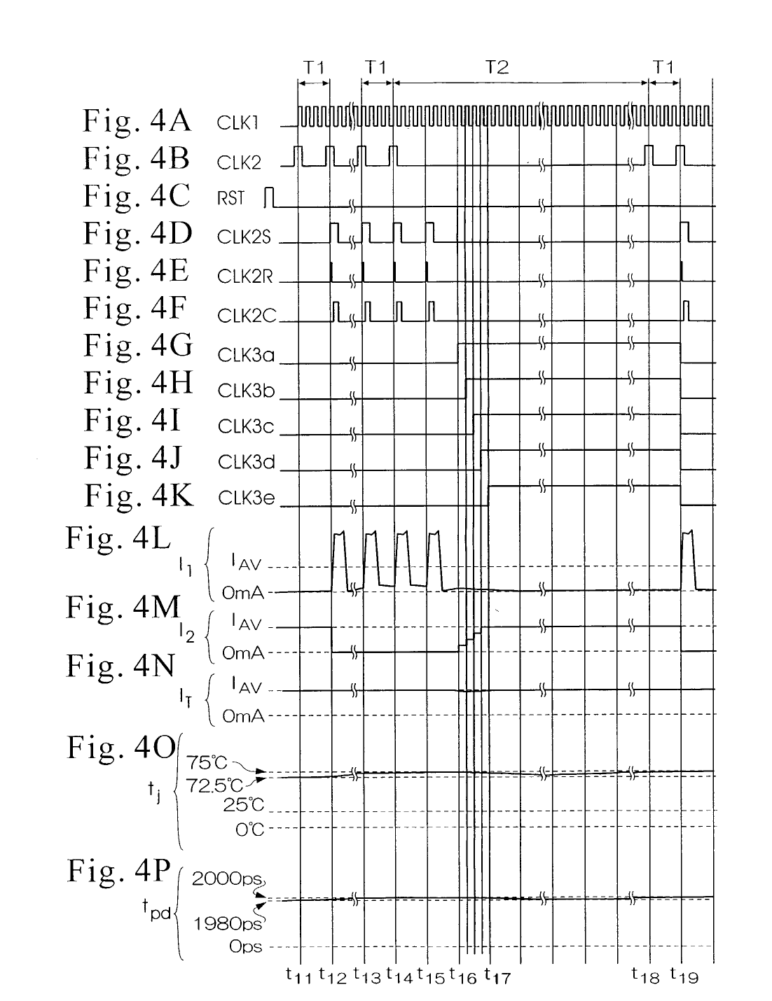

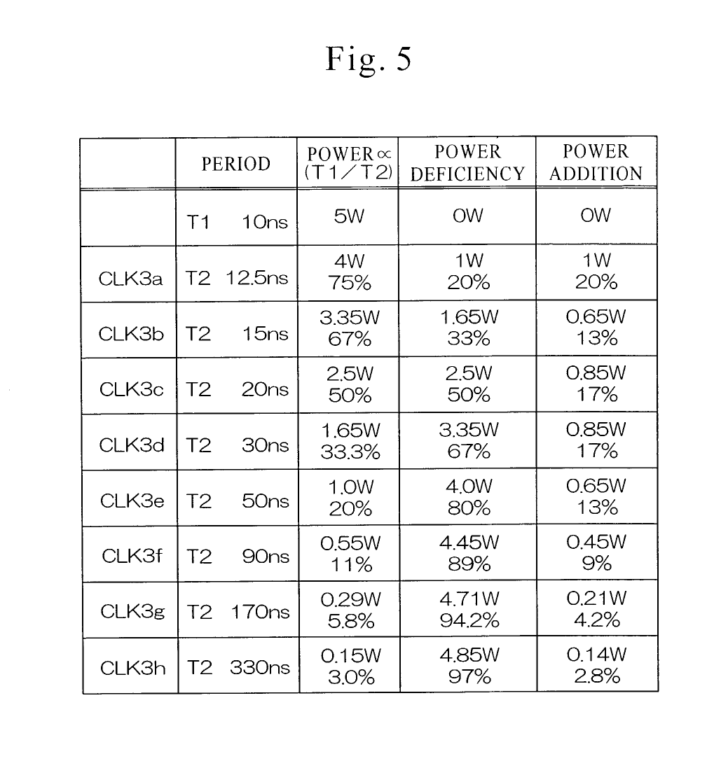

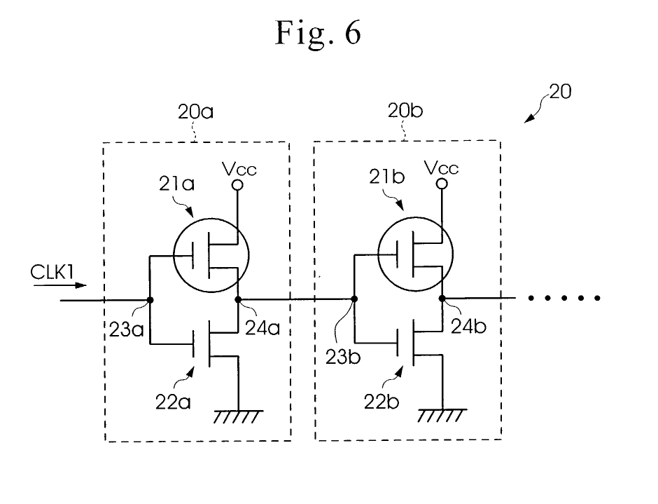

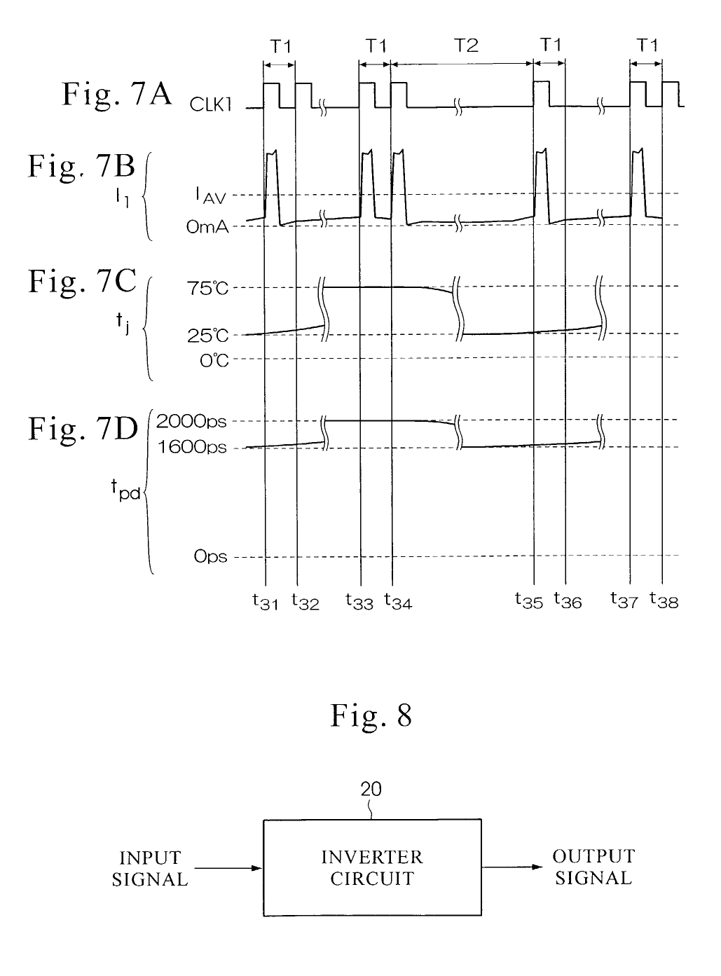

FIG. 4P is a time chart showing a response time t_{pd} of the logic circuit shown in FIG. 1;

FIG. 5 is a table showing relationships between power deficiencies of the logic circuit and power additions by the auxiliary logic circuits in connection with various periods of the clock signal CLK2;

FIG. 6 is a circuit diagram showing the typical example of a conventional CMOS inverter circuit;

FIG. 7A is a time chart showing a clock signal CLK1 input to the CMOS inverter circuit shown in FIG. 6;

FIG. 7B is a time chart showing a transient current I₁ that flows in a unit inverter of the CMOS inverter circuit;

FIG. 7C is a time chart showing a junction temperature tⱼ that is measured in the CMOS inverter circuit;

FIG. 7D is a time chart showing a response time t_{pd} that is measured in the CMOS inverter circuit; and

FIG. 8 is a simplified block diagram for the CMOS inverter circuit.

### DESCRIPTION OF THE PREFERRED EMBODIMENT

This invention will be described in further detail by way of examples with reference to the accompanying drawings.

FIG. 1 shows the configuration of a semiconductor integrated circuit in accordance with one embodiment of the invention. The semiconductor integrated circuit of the present embodiment is mainly constituted by logic circuit sections 10-1 and 10-2 as well as prescribed circuits controlling their operations.

The logic circuit section 10-1 contains a logic circuit 11-1 and auxiliary logic circuits 13a-13e. The logic circuit 11-1 is composed of numerous logic circuit elements, functions of which can be arbitrarily selected. The present embodiment provides an inverter circuit function for the logic circuit 11-1, which is hence constituted by unit inverters 12a to 12f in series. The logic circuit 11-1 is supplied with a clock signal CLK2S whose period (or frequency) is variable. Details of the clock signal CLK2S will be described later.

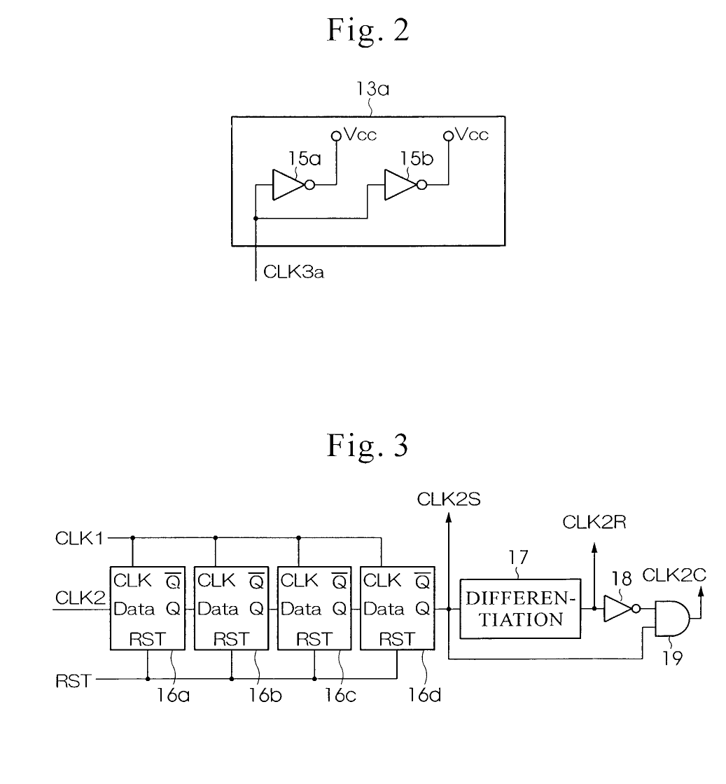

A series of the auxiliary logic circuits 13a to 13e are provided in correspondence with the logic circuit 11-1 . FIG. 2 shows an example of the internal configuration of the auxiliary logic circuit 13a, which is a representative selected from among the auxiliary logic circuits 13a-13e. The auxiliary logic circuit 13a shown in FIG. 2 is constituted by a pair of unit inverters 15a and 15b, which are provided in correspondence with a selected pair of unit inverters contained in the logic circuit 11-1. That is, the unit inverter 15a is formed relative to the unit inverter 12a, and the unit inverter 15b is formed relative to the unit inverter 12b.

When the logic circuit 11-1 is constituted to realize the inverter circuit function by connecting together numerous unit inverters 12a to 12f in series, the other auxiliary logic circuits 13b to 13e are each constituted similarly to the auxiliary logic circuit 13a shown in FIG. 2. That is, the present embodiment is designed in such a way that all the auxiliary logic circuits 13a to 13e are constituted similarly to each other in correspondence with the logic circuit 11-1.

It is preferable that the auxiliary logic circuits 13a to 13e are formed in proximity to the logic circuit 11-1. In addition, it is possible to provide the similar configuration for the unit inverters 12a to 12f of the logic circuit 11 -1, and for the unit inverters 15a and 15b of the auxiliary logic circuit 13a (and other auxiliary logic circuits 13b-13e). For example, these unit inverters can be constituted similar to the foregoing unit inverter 20a, which is composed of a pair of the PMOS transistor 21a and the NMOS transistor 22a shown in FIG. 6.

In order to constitute each of the aforementioned unit inverters 12a-12f, 15a, and 15b by a pair of CMOS transistors and the like, it is necessary to set the prescribed relationship in dimensions among them. Specifically, the transistor size (or gate width) for the PMOS and NMOS transistors contained in the unit inverters 15a and 15b is set 1/n (where ‘n’ is a natural number arbitrarily selected) times smaller than the transistor size (or gate width) for the PMOS and NMOS transistors contained in the unit inverters 12a-12f The aforementioned setup in dimensions ensures that the average current flowing in the logic circuit 11-1 substantially matches the average current flowing in the auxiliary logic circuits 13a-13e.

The aforementioned configuration of the logic circuit section 10-1 is similarly applied to the other logic circuit section 10-2. That is, the logic circuit section 10-2 is constituted by a logic circuit having an inverter circuit function as well as its corresponding auxiliary logic circuits.

Next, a description will be given with respect to a control circuit section for controlling the logic circuit section 10-1. This control circuit section is constituted by numerous D flip-flops 14a to 14h that are connected together in a cascade-connection manner, wherein the output terminal (Q) of one flip-flop is connected to the data input terminal (Data) of its following flip-flop. Each flip-flop provides various terminals, namely, the clock terminal (CLK), data input terminal (Data), reset terminal (RST), output terminal (Q), and inverted output terminal (\overline{Q}) which is not used. The reset signal CLK2R is supplied to all the reset terminals RST of the D flip-flops 14a-14h, while the clock signal CLK1 is supplied to all the clock terminals CLK of the D flip-flops 14a-14h. The data input terminal (Data) of the first D flip-flop 14a is set to the source voltage (VCC). In addition, the clock signal CLK2C is supplied to only the clock terminal CLK of the first D flip-flop 14a.

Among the aforementioned D flip-flops 14a-14h, the first three D flip-flops 14a-14c are merely connected together in series. The output terminal (Q) of the fourth D flip-flop is connected to the auxiliary logic circuit 13a; the output terminal (Q) of the fifth D flip-flop 14e is connected to the auxiliary logic circuit 13b; the output terminal (Q) of the sixth D flip-flop 14f is connected to the auxiliary logic circuit 13c; the output terminal (Q) of the seventh D flip-flop 14g is connected to the auxiliary logic circuit 13d; and the output terminal (Q) of the eighth D flip-flop 14h is connected to the auxiliary logic circuit 13e. That is, the auxiliary logic circuits 13a to 13e are supplied with clock signals CLK3a to CLK3e from the D flip-flops 14d to 14h respectively.

All the D flip-flops 14a to 14h are combined together to construct a selection circuit for selectively activating each of the auxiliary logic circuits 13a to 13e in response to the period of the clock signal CLK2S input to the logic circuit 11-1. Next, a description will be given with respect to a clock generator circuit that generates the clock signal CLK2S for the logic circuit 11-1 as well as the clock signal CLK2C and reset signal CLK2R for the selection circuit composed of the D flip-flops 14a to 14h.

FIG. 3 shows an example of the configuration of the clock generator circuit that generates the clock signals CLK2S and CLK2C as well as the reset signal CLK2R. The clock generator circuit shown in FIG. 3 contains a series of D flip-flops 16a to 16d, which are connected together in a cascade-connection manner such that the output terminal (Q) of one flip-flop is connected to the data input terminal (Data) of its following flip-flop. In addition, the clock generator circuit also contains a differentiation circuit 17, an inverter circuit 18, and an AND circuit 19. Herein, the differentiation circuit 17 is connected to the output terminal of the D flip-flop 16d. The output terminal of the differentiation circuit 17 is connected to the first input of the AND circuit 19 via the inverter circuit 18, while the output terminal of the D flip-flop 16d is directly connected to the second input of the AND circuit 19. Similar to the foregoing D flip-flops 14a-14h, the D flip-flops 16a-16d each provide the clock terminal (CLK), data input terminal (Data), reset terminal (RST), output terminal (Q), and inverted output terminal (\overline{Q}) which is not used.

The reset signal RST is supplied to all the reset terminals of the D flip-flop 16a-16d. In addition, the first clock signal CLK1 is supplied to all the clock terminals of the D flip-flops 16a-16d respectively. The second clock signal CLK2 is supplied to only the data input terminal (Data) of the first D flip-flop 16a. The second clock signal CLK2 is defined as the prescribed ‘variable’ signal that is supplied to the logic circuit and whose period can be arbitrarily varied but cannot be reduced under the prescribed ‘shortest’ period (e.g., 10 ns).

In contrast to the second clock signal CLK2, the first clock signal has the period that is shorter than the prescribed shortest period. For convenience' sake, the period of the first clock signal CLK1 is set to a quarter of the prescribed shortest period T1 set for the second clock signal CLK2. That is, when T1 equals 10 ns, the period of the first clock signal CLK1 is 2.5 ns, for example. In the present embodiment, the logic circuit 11-1 is supplied with the clock signal CLK2S that is delayed from the second clock signal CLK2 by the prescribed shortest period T1.

Next, the overall operation of the semiconductor integrated circuit of the present embodiment will be described in detail with reference to FIGS. 1 to 3 in connection with time charts shown in FIGS. 4A to 4P. FIGS. 4A to 4K show the aforementioned clock signals and reset signal. FIG. 4L shows a transient current I₁ that flows in the logic circuit 11-1, wherein the transient current I₁ may contain the charging current, discharging current, and through current. FIG. 4M shows a current I₂ that flows through each of the auxiliary logic circuits 13a to 13e. FIG. 4N shows a total current I_{T} that is a sum of the average of the transient current I₁ and the average of the current 12. FIG. 40 shows a junction temperature t^{j}, that is measured in the semiconductor integrated circuit shown in FIG. 1. FIG. 4P shows a response time t_{pd} of the logic circuit 11-1, wherein details of the response time t_{pd} have been already described before with reference to FIG. 7D and FIG. 8.

Upon receipt of the reset signal RST (or a reset pulse) shown in FIG. 4C, the D flip-flops 16a-16d of the clock generator circuit of FIG. 3 are each reset. The first clock signal CLK1 shown in FIG. 4A has the certain period (e.g., 2.5 ns) and is supplied to the D flip-flops 16a-16d shown in FIG. 3 as well as the D flip-flops 14b-14h shown in FIG. 1 respectively.

During the time period between t₁₁, and t₁₄, clock pulses of the second clock signal CLK2 having the prescribed shortest period T1 (e.g., 10 ns) are sequentially input to the clock generator circuit of FIG. 3. During this time period, the second clock signal CLK2 as a whole is delayed by the prescribed shortest period T1 thereof in the D flip-flops 16a-16d, so that the last D flip-flop 16d outputs the clock signal CLK2S, which is delayed from the second clock signal CLK2 by T1. The clock signal CLK2S is input to the differentiation circuit 17, which in turn produces the reset signal CLK2R. The reset signal CLK2R contains a string of pulses that respectively represent leading edges of pulses of the clock signal CLK2S. The inverter 18 inverts the reset signal CLK2R, which is then supplied to the first input of the AND circuit 19. Therefore, the AND circuit 19 outputs a logical product calculated between the ‘inverted’ reset signal CLK2R and the clock signal CLK2S, wherein the logical product is referred to as the clock signal CLK2C.

The clock signal CLK2S is supplied to the logic circuit 11-1; the clock signal CLK2C is supplied to the clock terminal (CLK) of the D flip-flop 14a; and the reset signal CLK2R is supplied to the reset terminals (RST) of the D flip-flops 14a-14h respectively. That is, the D flip-flops 14a-14h are respectively supplied with the reset signal CLK2R consisting of pulses, which represent leading edges of pulses of the clock signal CLK2S. Hence, all the D flip-flops 14a-14h are reliably reset at each of the leading-edge timings of the clock signal CLK2S. When all the D flip-flops 14a-14h are simultaneously reset, the D flip-flop 14a receiving the clock signal CLK2C (see FIG. 4F) provides a high (H) level at the output terminal (Q) thereof The aforementioned first clock signal CLK1 consisting of pulses that periodically rise and fall (see FIG. 4A) is input to the clock terminals (CLK) of the D flip-flops 14a-14h. Every time a clock pulse is input to the D flip-flops 14a-14h, the output level of the preceding one is transferred to the output terminal of the following one. That is, in response to the clock pulses that are sequentially input to the D flip-flops 14a-14h, the output level of the first D flip-flop 14a is sequentially transferred to the output terminals of the other D flip-flops 14b-14h. Hence, after the pulse of the reset signal CLK2R is simultaneously input to the D flip-flops 14a-14h, the first D flip-flop 14a provides a high level at the output terminal (Q) thereof due to a pulse of the clock signal CLK2C; then, the second D flip-flop 14b provides a high level at the output terminal (Q) thereof in response to a pulse of the first clock signal CLK1; thereafter, the third D flip-flop 14c provides a high level at the output terminal (Q) thereof in response to a next pulse of the first clock signal CLK1. When the prescribed shortest period T1 completely elapsed so that a next pulse of the second clock signal CLK2 is input to the clock generator circuit of FIG. 3, a pulse of the reset signal CLK2R representing the leading edge timing of the pulse of the clock signal CLK2S is correspondingly input to the D flip-flops 14a-14h, which are simultaneously reset. Therefore, during the time period in which pulses of the second clock signal CLK2 having the prescribed shortest period TI are sequentially supplied to the clock generator circuit of FIG. 3, all the D flip-flops 14a-14h are periodically reset every period T1 so that the D flip-flops 14d-14h cannot provide high levels at their output terminals (Q), in other words, they cannot output clock signals CLK3a-CLK3e to the auxiliary logic circuits 13a-13e respectively. Hence, in this time period, the auxiliary logic circuits 13a-13e do not operate at all.

Specifically, in the time period between t₁₂ and t₁₆, the clock signal CLK2S whose pulses periodically emerge at the same period T1 therebetween is supplied to the logic circuit 11-1, an average current I_{AV} representing an average of the transient current I₁ (see FIG. 4L) may flow in the logic circuit 11-1. In this time period, the junction temperature tⱼ that is initially at 72.5° C. is gradually increased to 75° C., so that the response time t_{pd} that is initially 1980 ps is gradually increased to 2000 ps. The present embodiment describes properties of the semiconductor integrated circuit of FIG. 1 in such a way that in the time period in which pulses of the clock signal CLK2S periodically emerge at the same period T1 therebetween and are sequentially supplied to the logic circuit 11-1, the junction temperature tⱼ is gradually increased to 75° C. while the response time t_{pd} is gradually increased to 2000 ps. Of course, it is possible to easily vary these values by providing the heat radiation or dissipation means using the heatsink and the like.

As described above, in the time period t₁₂-t₁₆ in which pulses of the clock signal CLK2S periodically emerge at the same period T1 therebetween and are sequentially supplied to the logic circuit 11-1, none of the auxiliary logic circuit 13a-13e operate at all; hence, the aforementioned current I₂ remains zero. Therefore, the total current I_{T}, which is a sum of the average of the transient current I₁ flowing in the logic circuit 11-1 and the average of the current I₂ flowing in the auxiliary logic circuits 13a-13e, matches the average current I_{AV}.

At time t₁₄, the period of the second clock signal CLK2 is changed over from T1 to T2 (where T2>T1), so that the second clock signal CLK2 stops providing pulses thereafter. The ‘long’ period T2 for the second clock signal CLK2 is sustained in the time period between t₁₄ and t₁₈, so that no pulse of the second clock signal CLK2 is supplied to the clock generator circuit of FIG. 3 after time t₁₈ until time t₁₈. However, in response to the last pulse of the second clock signal CLK2 that emerges at time t₁₄, the clock generator circuit of FIG. 3 produces pulses for the clock signals CLK2S and CLK2C as well as the reset signal CLK2R at time t₁₅.

At time t₁₅, the last pulse of the reset signal CLK2R is supplied to the D flip-flops 14a-14h, which are simultaneously reset. In addition, the last pulse of the clock signal CLK2C is supplied to the D flip-flop 14a, which in turn provides a high level at the output terminal (Q) thereof In contrast, pulses of the first clock signal CLK1 are continuously and sequentially supplied to the D flip-flops 14a-14h, regardless of the changeover of the period of the second clock signal CLK2 from T1 to T2. Therefore, in response to the pulses of the first clock signal CLK1, the D flip-flops 14b and 14c sequentially provide a high level at their output terminals (Q).

At time t₁₅, the second clock signal CLK2 provides no pulse to the clock generator circuit of FIG. 3, so that the clock signal CLK2S provides no pulse to the logic circuit 11-1 at time t₁₆. As a result, the transient current I₁ flowing in the logic circuit 11-1 is reduced to be small. After time t₁₆, the reset signal CLK2R provides no pulse to the D flip-flops 14a-14h. Hence, at time t₁₆ when a pulse emerges in the first clock signal CLK1, the D flip-flop 14d provides a high level at the output terminal (Q) thereof. The D flip-flop 14d sustains the high level at the output terminal (Q) thereof for a while. That is, the D flip-flop 14d outputs the clock signal CLK3a having the high level, which is supplied to the auxiliary logic circuit 13a. Thus, the auxiliary logic circuit 13a operates and allows the current I₂ to flow therethrough.

Next, other pulses sequentially emerge in the first clock signal CLK1 and are supplied the D flip-flops 14a-14h. In response to a next pulse of the first clock signal CLK1, the D flip-flop 14e, which is next to the D flip-flop 14d, provides a high level at the output terminal (Q) thereof Since the high level is sustained for a while, the D flip-flop 14e outputs the clock signal CLK3b having the high level, which is supplied to the auxiliary logic circuit 13b. As a result, the auxiliary logic circuit 13b operates and allows the current I₂ to flow therethrough, wherein the current I₂ is a sum of the currents respectively flowing in the auxiliary logic circuits 13a and 13b. Similarly, when next pulses sequentially emerge in the first clock signal CLK1, the D flip-flops 14f to 14h sequentially provide high levels at their output terminals (Q), so that they output clock signals CLK3c to CLK3e having high levels, which are sequentially and respectively supplied to the auxiliary logic circuits 13c to 13e. Thus, the auxiliary logic circuits 13c to 13e respectively operate and allow currents to flow therethrough.

According to the present embodiment described above, when the period of the second clock signal CLK2 supplied to the clock generator circuit of FIG. 3 becomes greater than the prescribed shortest period T1, the selection circuit composed of the D flip-flops 14a-14h sequentially selects and activates the auxiliary logic circuits 13a-13e at different timings respectively. That is, the D flip-flops 14a-14h sequentially activate the auxiliary logic circuits 13a-13e, which are respectively selected at consecutive leading-edge timings of the first clock signal CLK1.

In the time period between t₁₆ and t₁₈, the clock signal CLK2S provides no pulse to the logic circuit 11-1, substantially no current flows in the logic circuit 11-1, whereas the auxiliary logic circuits 13a-13e sequentially operate and allow currents to flow therethrough. Therefore, the total current I_{T}, which represents the sum of the average of the transient current I₁ flowing in the logic circuit 11-1 and the average of the currents I₂ flowing in the auxiliary logic circuits 13a-13e, matches the average current I_{AV}.

In the above, even though no current flows in the logic circuit 11-1 for a long time, the average current I_{AV} flows in the auxiliary logic circuits 13a-13e respectively, so that the junction temperature tⱼ may be slightly reduced by 2.5° C. or so due to differences of transistor sizes and manufacturing errors. However, it can be said that substantially no variation occurs in the junction temperature tⱼ. For this reason, the response time t_{pd} may be slightly varied by 20 ps or so; and it can be said that the response time t_{pd} is normally stabilized to cause substantially no variation.

Just after the clock signal CLK2S provides no pulse to the logic circuit 11-1, the selection circuit sequentially selects and operates the auxiliary logic circuits 13a-13e at different timings respectively. Therefore, it is possible to control with fine precision on the total current I_{T} which represents the sum of the average of the transient current I₁ flowing in the logic circuit 11-1 and the average of the currents I₂ respectively flowing in the auxiliary logic circuits 13a-13e during the time period t₁₆t₁₇.

Thereafter, the period of the second clock signal CLK2 is changed over from T2 to T1, so that the second clock signal CLK2 provides a pulse to the clock generator circuit of FIG. 3 at time t₁₈. At time t₁₉, the clock signal CLK2S provides a pulse to the logic circuit 11-1 so that the logic circuit 11-1 allows a transient current to flow therethrough. At this time, the reset signal CLK2R also provides a pulse to the D flip-flops 14a-14h, which are simultaneously reset so that the clock signals CLK3a to CLK3e simultaneously become low. Hence, the D flip-flops 14d-14h stop supplying the clock signals CLK3a-CLK3e to the auxiliary logic circuits 13a-13e. As a result, no current flows in the auxiliary logic circuits 13a-13e respectively.

This invention is not necessarily limited to the present embodiment and can be freely modified within the scope of the invention. In the present embodiment, both the clock signals CLK1 and CLK2 synchronize with each other. Of course, these clock signals are not necessarily synchronized with each other. Hence, this invention can be easily modified to cope with the asynchronous relationship established between the clock signals CLK1 and CLK2.

The present embodiment is described in such a way that the auxiliary logic circuits 13a-13e are sequentially activated by consecutive periods of the clock signal CLK1 respectively. Of course, it is possible to arbitrarily set the sequence and operation timings for sequentially activating the auxiliary logic circuits 13a-13e. Suppose that the clock signal CLK1 has a period T_{CK1}. In this case, the auxiliary logic circuits 13a-13e are respectively controlled in their operation start timings in such a way that the auxiliary logic circuit 13a starts operation the time T_{CK1} later; the auxiliary logic circuit 13b starts operation the time 2×T_{CK1} later; the auxiliary logic circuit 13c starts operation the time 4×T_{CK1} later; the auxiliary logic circuit 13d starts operation the time 8×T_{CK1} later; and the auxiliary logic circuit 13e starts operation the time 16×T_{CK1} later. That is, it is possible to arbitrarily shift the operation start timings of the auxiliary logic circuits 13a-13e.

FIG. 5 shows relationships between electric power deficiencies and additions in the logic circuit 11-1 in connection with various periods of the clock signal CLK2. That is, when the clock signal CLK2 is supplied to the logic circuit 11-1 by the prescribed shortest period T1 (10 ns), power of 5 W is supplied to the logic circuit 11-1. When the period of the clock signal CLK2 is increased to 12.5 ns, the power supplied to the logic circuit 11-1 is decreased to 4 W. In this case, it is necessary to compensate for the power deficiency of 1 W in heat value by activating the auxiliary logic circuit(s). Specifically, only the auxiliary logic circuit 13a is activated to compensate for the power deficiency of 1 W.

When the period of the clock signal CLK2 is 15 ns, the power supplied to the logic circuit 11-1 is decreased to 3.35 W. In this case, it is necessary to compensate for the power deficiency of 1.65 W in heat value by activating the auxiliary logic circuit(s). Specifically, the auxiliary logic circuits 13a and 13b are activated to compensate for the power deficiency of 1.65 W. In summary, this invention does not require the same internal configuration for all the auxiliary logic circuits 13a-13e. That is, it is possible to arbitrarily design each of the auxiliary logic circuits 13a-13e in the aspect to compensate for the power deficiency in the logic circuit 11-1 in response to the period of the clock signal CLK2. In addition, it is possible to arbitrarily set the sequence for sequentially or adequately starting operations of the auxiliary logic circuits 13a-13e.

As described heretofore, this invention provides various technical features and effects, which will be described below.

(1) Each of the auxiliary logic circuits is arbitrarily selected in response to the period of the clock signal supplied to the logic circuit. Therefore, even though the clock signal having a relatively long period is supplied to the logic circuit to cause a reduction of the average current flowing in the logic circuit, the auxiliary logic circuits are adequately selected to allow currents flowing therethrough in response to the period of the clock signal supplied to the logic circuit. This may result in substantially no variation occurring in the junction temperature and jitter with respect to the transistors contained in the logic circuit.

(2) In the above, the auxiliary logic circuit(s) is adequately selected in response to the period of the clock signal supplied to the logic circuit. Therefore, it is possible to perform high-precision controls on variations of the junction temperature and jitter.

(3) As a result, it is possible to provide a semiconductor integrated circuit that is suitable for use in the highly accurate measuring device such as the semiconductor integrated circuit testing device.

As this invention may be embodied in several forms without departing from the spirit or essential characteristics thereof, the present embodiment is therefore illustrative and not restrictive, since the scope of the invention is defined by the appended claims rather than by the description preceding them, and all changes that fall within metes and bounds of the claims, or equivalents of such metes and bounds are therefore intended to be embraced by the claims.

What is claimed is:

1. A semiconductor integrated circuit comprising:
a logic circuit that operates in accordance with an input clock signal (CLK2S);
a plurality of auxiliary logic circuits that are provided relative to the logic circuit; and
a selection circuit for selecting at least one of the plurality of auxiliary logic circuits in response to a period of the input clock signal supplied to the logic circuit.

2. A semiconductor integrated circuit according to claim 1, wherein each of the auxiliary logic circuits has an internal configuration that partially resembles an internal configuration of the logic circuit.

3. A semiconductor integrated circuit according to claim 2, wherein each auxiliary logic circuit is composed of a pair of inverters that are provided in correspondence with a pair of inverters included in the logic circuit.

4. A semiconductor integrated circuit according to claim 1, wherein the selection circuit sequentially selects and activates the plurality of auxiliary logic circuits at different timings respectively.

5. A semiconductor integrated circuit according to claim 1 or 4, wherein the selection circuit is composed of a plurality of flip-flops for sequentially activating the plurality of auxiliary logic circuits respectively.

6. A semiconductor integrated circuit according to claim 1 or 4, wherein the selection circuit selects the plurality of auxiliary logic circuits respectively unless the period of the input clock signal supplied to the logic circuit is not smaller than a prescribed shortest period (T1) that is determined in advance.

7. A semiconductor integrated circuit according to claim 1 or 4, wherein the selection circuit sequentially selects and activates the plurality of auxiliary logic circuits at the different timings that are determined based on a reference clock signal (CLK1) whose period is shorter than the prescribed shortest period (T1).

8. A semiconductor integrated circuit according to claim 1, wherein the auxiliary logic circuits are formed in proximity to the logic circuit.

9. A semiconductor integrated circuit according to claim 1, wherein all the logic circuit and the auxiliary logic circuits are composed of CMOS transistors.

10. A semiconductor integrated circuit according to claim 1 or 9, wherein the logic circuit contains a plurality of transistors, and each of the auxiliary logic circuits contains at least one transistor whose size is 1/n (where ‘n’ is a natural number arbitrarily selected) times smaller than the size of the transistor contained in the logic circuit.

11. A semiconductor integrated circuit comprising:
a logic circuit that is composed of CMOS transistors;
a plurality of auxiliary logic circuits, each of which is composed of CMOS transistors, wherein the size of the CMOS transistor contained in each auxiliary logic circuit is 1/n (where ‘n’ is a natural number arbitrarily selected) times smaller than the size of the CMOS transistor contained in the logic circuit; and
a selection circuit for selectively activating the plurality of auxiliary logic circuits relatively with the logic circuit.

12. A semiconductor integrated circuit according to claim 11, wherein the logic circuit is constituted by a plurality of unit inverters each of which is composed of a pair of CMOS transistors, and each of the plurality of auxiliary logic circuits is constituted by a pair of unit inverters relative to an arbitrary pair of unit inverters contained in the logic circuit.

13. A semiconductor integrated circuit according to claim 11, wherein the selection circuit is constituted by a plurality of flip-flops, which selectively activate the plurality of auxiliary logic circuits.

14. A semiconductor integrated circuit according to claim 11, wherein the logic circuit operates in accordance with an input clock signal (CLK2S) whose period is not smaller than a prescribed shortest period (T1) that is determined in advance, and the selection circuit selectively activates the plurality of auxiliary logic circuits in accordance with a reference clock signal (CLK1) whose period is smaller than the prescribed shortest period.
